(19) United States
(12) Patent Application Publication
(10) Pub. No.: US 2008/0268642 A1
(43) Pub. Date: Oct. 30, 2008

(54) DEPOSITION OF TRANSITION METAL CARBIDE CONTAINING FILMS

(76) Inventors: Kazutaka Yanagita, Tsukuba-shi (JP); Christian Dussarrat, Wilmington, DE (US)

Correspondence Address: AIR LIQUIDE;Intellectual Property, 2700 POST OAK BOULEVARD, SUITE 1800, HOUSTON, TX, 77056, US

(21) Appl. No.: 12/106,480

(22) Filed: Apr. 21, 2008

Related U.S. Application Data
(60) Provisional application No. 60/913,210, filed on Apr. 20, 2007.

(51) Int. Cl. H01L 21/285

(52) U.S. Cl. 438/680; 257/E21.16

(57) ABSTRACT

Methods and compositions for the deposition of a transition metal containing film in a semiconductor manufacturing process. A first vaporized metal precursor is introduced into a reaction chamber along with a second precursor mixture which comprises at least one carbon source. The reaction chamber contains at least one substrate, and a metal containing film is formed on the substrate through a deposition process

### CROSS REFERENCE TO RELATED APPLICATIONS

The present application claims the benefit of U.S. Provisional Application Ser. No. 60/913,210, filed Apr. 20, 2007, herein incorporated by reference in its entirety for all purposes.

### BACKGROUND

1. Field of the Invention

This invention relates generally to the field of semiconductor fabrication. More specifically, the invention relates to a method of depositing a transition metal containing film on a substrate.

2. Background of the Invention

The dramatic shrinkage in the dimensions of future CMOS semiconductor devices raises many challenges for which new materials are sought. One of these challenges arises in the form of the dual metal gate which will be required along with high dielectric (“high-k”) materials for the CMOS stack. The metal gate will likely be required to achieve a 0.2 V threshold voltage, which will allow for drastically reduced power consumption by the devices.

These metal gates will likely be made from two metal compounds, each having a different work function (e.g. ˜5 eV for the pMOS gate, and ˜4 eV for the nMOS gate). The materials which will be used for these gates will need to be optimized with respect to several material properties, such as: resistivity, work function (which can be affected by the presence of other elements in the metal film), thermal stability, adhesion, and etch selectivity.

Transition metal, particularly Group V metal, containing films show promise as suitable materials for metal gate applications. In particular, tantalum based materials such as tantalum carbide, tantalum silicide, tantalum silico-nitride, and tantalum carbo-nitride show promise as suitable materials for these metal gate applications. Many current methods to deposit these materials require deposition at high temperatures or high pressures, neither of which is ideal from a manufacturing perspective.

Consequently, there exists a need for methods and compositions to form a transition metal containing films at low temperatures, for semiconductor manufacturing processes.

### BRIEF SUMMARY

Novel formulations and methods for depositing a transition metal containing film are described herein. The disclosed methods and formulations utilize a mixture of precursors which are then deposited on a substrate to form a thin film layer. These methods and formulations may be especially suited in the manufacture of semiconductor devices.

In an embodiment, a first vaporized metal precursor is introduced into a reaction chamber, where the first vaporized metal precursor has a general formula of M¹Xₘ or M¹XₘAB. M is a transition metal comprising Ta, Nb, Mo, W, Hf, and Zr, and m is an integer representing the oxidation state of the transition metal M¹. X is a halogen, and A is an O, S, or N atom. B is an alkyl group having 1 to 4 carbon atoms. A second precursor mixture which comprises a carbon source and at least one of a Si or a N atom is also introduced into the chamber, which contains one or more substrates. A metal containing film is then formed on the substrate through a deposition process.

Other embodiments of the invention may include, without limitation, one or more of the following:
the second precursor mixture comprises either an alkylsilane having the general formula SiHₓR₄₋ₓ, or an alkyldisilane having from 0 to 3, y is an integer ranging from 0 to 6, and R is an alkyl group having 1 to 4 carbon atoms;
the second precursor mixture comprises an alkylsilazane having the general formula NHₓ(SiH_{y}R_{4-y})₃₋ₓ, where x is an integer ranging from 0 to 3, y is an integer ranging from 0 to 2, and R is an alkyl group having 1 to 4 carbon atoms;
the second precursor comprises monomethylsilane, dimethylsilane, trimethylsilane, tetramethylsilane, ethylsilane derivatives, propylsilane derivatives, and mixtures thereof;
the halogen is Cl;
M is Ta;
an inert gas or inert gas mixture (e.g. N₂, Ar, He) is injected into the reaction chamber;
a reducing gas mixture comprising hydrogen is introduced into the reaction chamber;
the metal containing film is formed on the substrate through a chemical vapor deposition, an atomic layer deposition, or a pulsed chemical vapor deposition process;
the first vaporized metal precursor and the second precursor mixture are introduced to the chamber with flow rates such that the respective flow rate ratio is between about 100:1 to about 1:100, preferably between about 1:1 to about 1:20;
the first vaporized metal precursor and the second precursor mixture are introduced to the chamber with flow rates such that the respective flow rate ratio is between about 10:1 to about 1:100, preferably between about 1:1 to about 1:10;
the first vaporized metal precursor and the second precursor mixture is introduced into the chamber in an excited state resulting from a plasma enhancement or a light excitation;
the deposition process is performed with a plasma enhancement or a light excitation;
the deposition process is performed at a temperature between about 300 C and about 600 C; preferably between about 350 C and 500 C; and
the deposition is performed at pressure less than about 100 Torr; preferably between about 0.1 to about 100 Torr.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and the specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### Notation and Nomenclature

Certain terms are used throughout the following description and claims to refer to particular system components. This document does not intend to distinguish between components that differ in name but not function.

In the following discussion and in the claims, the terms “including” and “comprising” are used in an open-ended fashion, and thus should be interpreted to mean “including, but not limited to . . . .

As used herein, the abbreviation “Me” refers to a methyl (CH₃₋) group, the abbreviation “Et” refers to an ethyl (CH₄CH₂₋) group, and the abbreviation “Bu” refers to a butyl group.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

### BRIEF DESCRIPTION OF THE DRAWINGS

For a further understanding of the nature and objects for the present invention, reference should be made to the following detailed description, taken in conjunction with the accompanying drawings, in which like elements are given the same or analogous reference numbers and wherein:

FIG. 1 illustrates graphical results of a deposition, according to one embodiment of the current invention, of a metal containing film; and

FIG. 2 illustrates graphical results of a deposition, according to another embodiment of the current invention, of a metal containing film.

### DESCRIPTION OF PREFERRED EMBODIMENTS

In an embodiment, a first vaporized metal precursor is introduced into a reaction chamber, where the first vaporized metal precursor has a general formula of M¹Xₘ or M¹XₘAB. M is a transition metal comprising Ta, Nb, Mo, W, Hf, and Zr, and m is an integer representing the oxidation state of the transition metal M¹. X is a halogen, and A is an O, S, or N atom. B is an alkyl group having 1 to 4 carbon atoms. A second precursor mixture which comprises a carbon source and one of a Si or a N atom is also introduced into the chamber, which contains one or more substrates. A metal containing film is then formed on the substrate through a deposition process. In some embodiments, the transition metal M¹ is tantalum.

In some embodiments, the first vaporized metal precursor may contain a tantalum halide, such as tantalum pentachloride TaCl₅, tantalum pentafluoride TaF₅, tantalum pentabromide TaBr₅, and their sulfur adducts, preferably, TaCl₅ or TaCl₅-S(C₂H₅)₂. In some embodiments the tantalum source is TaL₅, or TaL₅-S(R¹)₂ (where R¹=H or alkyl, L=F, Cl, or Br).

In some embodiments the second precursor mixture comprises an alkylsilane, or an alkyldisilane, such as a poly-methyl silanes which include without limitation: trimethylsilane (3MS), tetramethylsilane (4MS), 1,1,1,3,3,3-hexamethyldisilane, (SiₓH_{(3-y)})(CH₃)_{y} where (x=1,2,3, y=1˜x*2+2) or (CH₃)ₓSiH₍₄₋ₓ₎ where (x=1,2,3).

In some embodiments the second precursor mixture comprises a silazane which includes, without limitation: 1,1,1,3,3,3-hexamethyldisilazane (HMDS), 1,1,3,3-tetramethyidisilazane (TMDS), and ((CH₃)ₓSiH₍₃₋ₓ₎)_{y}NH(_{3-y)} where x=1,2,3, and where y=1,2,3.

The disclosed precursor compounds may be deposited using any deposition methods known to those of skill in the art. Examples of suitable deposition methods include without limitation, conventional CVD, low pressure chemical vapor deposition (LPCVD), atomic layer deposition (ALD), pulsed chemical vapor deposition (P-CVD), plasma enhanced atomic layer deposition (PE-ALD) plasma enhanced chemical vapor deposition (PE-CVD), or combinations thereof. In an embodiment, a first vaporized metal precursor and a second precursor mixture may be introduced into a reaction chamber. The reaction chamber may be any enclosure or chamber within a device in which deposition methods take place such as without limitation, a cold-wall type reactor, a hot-wall type reactor, a single-wafer reactor, a multi-wafer reactor, or other types of deposition systems under conditions suitable to cause the precursors to react and form the layers.

In some embodiments, the precursor compounds may be deposited in an excited state, which results from a plasma enhancement or a light excitation, In some embodiments, the plasma enhancement or light excitation occurs prior to the precursors' introduction into the reaction chamber, and in some embodiments the precursors are exposed to the plasma enhancement or light excitation while in the reaction chamber.

One of ordinary skill in the art would recognize that plasma enhancement and light excitation are conventional techniques used in the deposition of films in semiconductor manufacturing (e.g. plasma enhanced chemical vapor deposition). By exposing precursors to a plasma enhancement or light excitation, either before or after their introduction to a reaction chamber, the precursors may experience a change in structure (e.g. breaking of bonds) that facilitates their deposition onto a substrate. In some cases, the plasma enhancement or light excitation allows for depositions of precursors at temperatures lower than what would be possible if only thermal techniques were used.

Generally, the reaction chamber contains one or more substrates on to which the metal films will be deposited. The one or more substrates may be any suitable substrate used in semiconductor manufacturing. Examples of suitable substrates include without limitation, silicon substrates, silica substrates, silicon nitride substrates, silicon oxy nitride substrates, tungsten substrates, or combinations thereof.

The first vaporized metal precursor and the second precursor mixture may be introduced sequentially (as in ALD) or simultaneously (as in CVD) into the reaction chamber. In one embodiment, the first and second precursors may be pulsed sequentially or simultaneously (e.g. pulsed CVD) into the reaction chamber. Each pulse of the first vaporized metal precursor and/or second precursor mixture may last for a time period ranging from about 0.01 s to about 10 s, alternatively from about 0.1 s to about 5 s, alternatively from about 1 s to about 3 s. These pulses may then occur repeatedly, for instance, several hundred or several thousand times.

In some embodiments, and without being limited to theory, a tantalum carbide film may be formed from a tantalum halide and a methylsilane where a ligand exchange occurs to form a tantalum methyl bond, which then further leads to the deposition of tantalum carbide through the evolution of the volatile chloromethylsilane. This mechanism may generally be shown as follows:

TaCl₅+Me—SiR₃→Cl₄TaMe+ClSiR₃.

The early transition metal to methyl bond is unstable, for example TaMe₅, HfMe₄, TiMe₄, WMe₆ could not be isolated (or decomposed just after) and CH₃ bonded to the early transition metal is then extremely reactive, enabling the formation of carbon bridge between several early transition metal.

Cl₄TaMe+TaCl₅→Cl₄Ta—CH₂-TaCl₄

This mechanism therefore allows the formation of early transition metal carbide, both in CVD, where it occurs in the gas phase, or in ALD regime where the early transition metal, earlier chemisorbed, is methylated in the surface during the pulse of the methylsilane, and where the resulting early transition metal methyl is a reactive site to the early transition metal halide later pulsed.

This mechanism may also be generally shown by:

TaCl_{x(abs)}+yMeSiR₃→TaCl_{x-y}Me_{y}

TaCl_{x-y}Me_{y}+TaCl₅→TaCl_{x-y}-CH₂-TaCl₄

### EXAMPLES

The following non-limiting examples are provided to further illustrate embodiments of the invention. However, the examples are not intended to be all inclusive and are not intended to limit the scope of the inventions described herein.

### Example 1

Thermal CVD of TaC Film from TaCl₅-S(C₂H₅)₂ and Hexamethyidisilazane (HMDS)

Films were successfully deposited, according to an embodiment of the current invention, by thermal CVD using two precursor sources, TaCl₅-S(C₂H₅)₂ and HMDS. The chamber was a hot-wall type reactor heated by a conventional heater. Both of precursor sources were constantly introduced to the reactor by bubbling them with accompanying sources of nitrogen carrier gas. The temperature conditions for the source supplies were 110 C for TaCl₅-S(C₂H₅)₂, 25 C for the HMDS, and 120 C for the associated transfer lines.

The reactors were held between 400 C˜500 C, and at a pressure of about 1 Torr. TaC films were deposited on typical Si wafers or SiO2 substrates. The deposited films included Ta and C contents and few percents of impurities according to in-depth analysis by Auger.

Deposition rates at typical conditions are 10 A/min at 400 C, 15 A/min at 500 C.

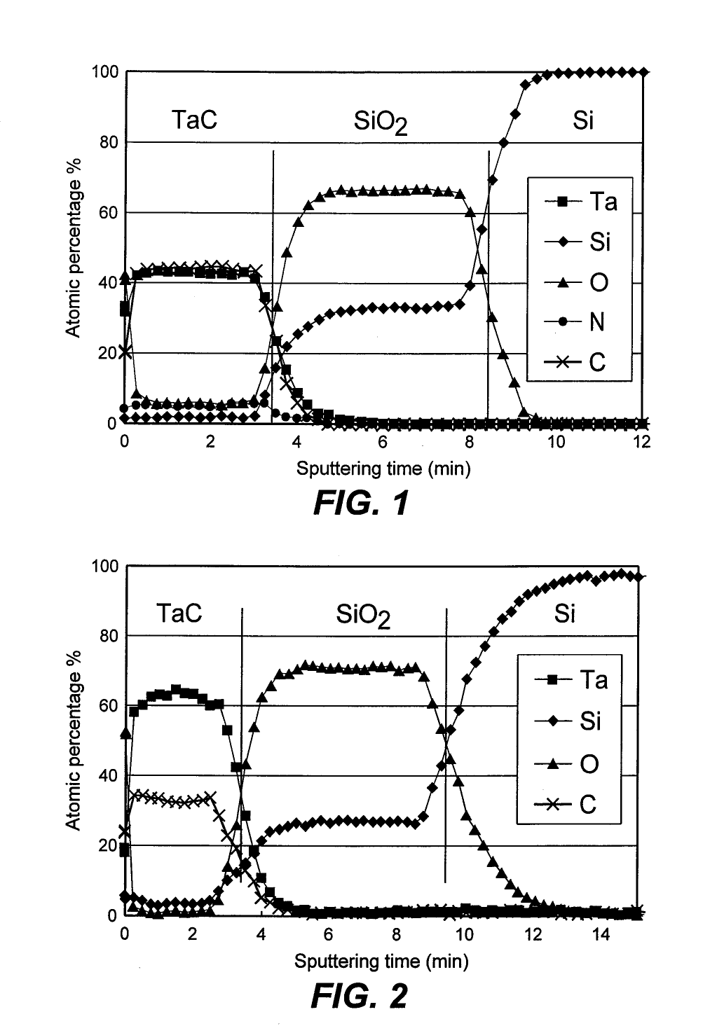

FIG. 1 shows AES analysis results for a TaC film deposited on SiO₂ from TaCl₅-S(C₂H₅)₂ and HMDS (temperature 400 C, pressure 1 Torr, time 90 minutes).

### Example 2

Thermal CVD of TaC Film from TaCl₅-S(C₂H₅)₂ and 3 MS

Films were successfully deposited, according to an embodiment of the current invention, by thermal CVD using two precursor sources, TaCl₅-S(C₂H₅)₂ and 3 MS and/or hydrogen. The chamber was hot-wall type reactor heated by a conventional heater. A tantalum precursor source was constantly introduced to the reactor by bubbling with by accompanying source of nitrogen carrier gas, and the 3 MS and hydrogen were flown into furnace controlling their flows with a mass flow controller. The temperature condition for the source supplies was 110 C for TaCl₅-S(C₂H₅)₂ and 120 C for the associated transfer lines.

The reactors were held between 400 C˜600 C, at a pressure between 1-5 Torr. TaC films were obtained on Si wafers or on a SiO₂ substrates. The deposited films are included Ta and C contents and few percents of impurities according to in-depth analysis by Auger. In this process, the hydrogen gas addition could reduce at the reaction temperature.

FIG. 2 shows AES analysis results for a TaC film deposited on SiO₂ from TaCl₅-S(C₂H₅)₂, 3 MS, and hydrogen. (Temperature 450 C, pressure 2 Torr, time 120 minutes).

While embodiments of this invention have been shown and described, modifications thereof can be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

What is claimed is:

1. A method for forming a transition metal containing film in a semiconductor manufacturing process, comprising:
a) introducing a first vaporized metal precursor into a reaction chamber, wherein the first vaporized metal precursor comprises at least one member selected from the group consisting:
1) of a compound having the formula:
M¹Xₘ
wherein M₁ is a transition metal selected from the group consisting of Ta, Nb, Mo, W, Hf, and Zr, m is an integer representing the oxidation state of the transition metal M¹, and X is a halogen; and
2) a compound having the formula:
M¹XₘAB
wherein M¹ is a transition metal selected from the group consisting of Ta, Nb, Mo, W, Hf, and Zr, m is an integer representing the oxidation state of the transition metal M¹, X is a halogen, A is an O, S, or a N atom, and B is an alkyl group having 1 to 4 carbon atoms;
b) introducing a second precursor mixture into the reaction chamber, wherein the second precursor mixture comprises a carbon source and at least one of a Si or a N atom, and the reaction chamber contains one or more substrates, and
c) forming a metal containing film on the substrate through a deposition process.

2. The method of claim 1, wherein the second precursor mixture comprises at least one member selected from the group consisting of:
a) an alkylsilane having the general formula:
SiHₓR₄₋ₓ; and
b) an alkyldisilane having the general formula:
Si₂H_{y}R₆₋ₓ;
wherein x is an integer ranging from 0 to 3, y is an integer ranging from 0 to 6, and R is an alkyl group having 1 to 4 carbon atoms.

3. The method of claim 1, wherein the second precursor mixture comprises an alkylsilazane having the general formula:
NHₓ(SiH_{y}R_{4-y})₃₋ₓ;
wherein x is an integer ranging from 0 to 3, y is an integer ranging from 0 to 2, and R is an alkyl group having 1 to 4 carbon atoms.

4. The method of claim 1, wherein the second precursor comprises at least one member selected from the group consisting of: monomethylsilane, dimethylsilane, trimethylsilane, tetramethylsilane, ethylsilane derivatives, propylsilane derivatives, and mixtures thereof.

5. The method of claim 1, wherein the halogen is chlorine.

6. The method of claim 1, wherein the transition metal is tantalum.

7. The method of claim 1, further comprising introducing an inert gas mixture into the reaction chamber.

8. The method of claim 1, further maintaining the reaction chamber, during the deposition process, at pressure less than about 100 Torr, and at a temperature between about 300 C and about 600 C.

9. The method of claim 1, further comprising introducing a reducing gas comprising hydrogen into the reaction chamber.

10. The method of claim 1, further comprising:
a) introducing the first vaporized metal precursor and the second precursor mixture at a flow rate ratio, respectively, of between about 100:1 to about 1:100; and
b) forming a metal containing film on the substrate through a chemical vapor deposition process.

11. The method of claim 10, wherein the flow rate ratio is between about 1:1 to about 1:20.

12. The method of claim 10, further comprising introducing either the first vaporized metal precursor or the second precursor mixture into the chamber in an excited state, wherein the excited state results from a plasma enhancement or a light excitation.

13. The method of claim 10, wherein the chemical vapor deposition is performed with plasma enhancement or light excitation.

14. The method of claim 1, further comprising:
a) introducing the first vaporized metal precursor and the second precursor mixture at a flow rate ratio, respectively, of between about 10:1 to about 1:100; and
b) forming a metal containing film on the substrate through an atomic layer deposition process.

15. The method of claim 14, wherein the flow rate ratio is between about 1:1 to about 1:10.

16. The method of claim 14, further comprising introducing either the first vaporized metal precursor or the second precursor mixture into the chamber in an excited state, wherein the excited state results from a plasma enhancement or a light excitation.

17. The method of claim 14, wherein the atomic layer deposition is performed with plasma enhancement or light excitation.

18. The method of claim 1, further comprising:
a) introducing the first vaporized metal precursor and the second precursor mixture at a flow rate ratio, respectively, of between about 10:1 to about 1:100; and
b) forming a metal containing film on the substrate through a pulsed chemical vapor deposition process where the vaporized metal precursor is intermittently introduced into the reactor.

19. The method of claim 18, wherein the flow rate ratio is between about 1:1 to about 1:10.

20. The method of claim 18, further comprising introducing either the first vaporized metal precursor or the second precursor mixture into the chamber in an excited state, wherein the excited state results from a plasma enhancement or a light excitation.

21. The method of claim 18, wherein the pulsed chemical vapor deposition is performed with plasma enhancement or light excitation.
